(19) United States
(12) Patent Application Publication
(10) Pub. No.: US 2025/0335679 A1
(43) Pub. Date: Oct. 30, 2025

(54) METHOD FOR SIMULATING MULTI-LEVEL CASCADED CIRCUITS IN BIT-STREAM PROCESSING SYSTEMS

(71) Applicant: UNIVERSITY OF LOUISIANA LAFAYETTE, Lafayette, LA (US)

(72) Inventors: Mohammadhassan NAJAFI, Lafayette, LA (US); Sercan AYGUN Sercan AYGUN, Lafayette, LA (US); Ece Olcay GUNES, Lafayette, LA (US)

(73) Assignee: UNIVERSITY OF LOUISIANA LAFAYETTE, Lafayette, LA (US)

(21) Appl. No.: 19/195,526

(22) Filed: Apr. 30, 2025

Related U.S. Application Data
(60) Provisional application No. 63/640,499, filed on Apr. 30, 2024.

(51) Int. Cl. G06F 30/3308

(52) U.S. Cl. CPC G06F 30/3308

(57) ABSTRACT

A method for contingency table-based bit-stream simulation to enhance simulation speed and precision in systems comprising reconvergent bit-stream paths. By utilizing the disclosed method, which relies on scalar-based processing, users may reduce the probability of correlation errors in design.

### CROSS-REFERENCE TO RELATED APPLICATIONS

This application claims priority to U.S. Provisional Application No. 63/640,499 filed on Apr. 30, 2024 titled “Method for Simulating Bit-Stream Processing Computing Systems.”

### STATEMENT REGARDING FEDERALLY SPONSORED RESEARCH OR DEVELOPMENT

The invention disclosed herein was funded in part by the National Science Foundation Grant Nos. 2019511 and 2339701.

### REFERENCE TO A “SEQUENCE LISTING,” A TABLE, OR A COMPUTER PROGRAM

Appendix 1 provides an embodiment of an implementation of a 2-bit ripple carry adder with inherit reconvergent paths, which provides the combinational circuit design for a stochastic simulation as a complex circuit with reconvergent path analysis for no reconvergence awareness in scalar (CT) processing, programmed in MATLAB®.

Appendix 2 provides an embodiment of an implementation of a 2-bit ripple carry adder with inherit reconvergent paths, which provides the combinational circuit design for a stochastic simulation as a complex circuit with reconvergent path analysis for the reconvergence awareness in scalar (CT) processing, programmed in MATLAB®.

### FIELD OF THE INVENTION

The field of the invention is directed towards stream processing, namely the simulation of processing of bitstreams in stochastic computing systems.

### BRIEF DESCRIPTION OF THE DRAWINGS

The drawings constitute a part of this specification and include exemplary embodiments of the METHOD FOR SIMULATING MULTI-LEVEL CASCADED CIRCUITS IN BIT-STREAM PROCESSING SYSTEMS, which may be embodied in various forms. It is to be understood that in some instances, various aspects of the invention may be shown exaggerated or enlarged to facilitate an understanding of the invention. Therefore, the drawings may not be to scale.

FIG. 1 depicts the scalar processing and formulas for processing two bit-stream operands, where each bit overlaps at every position.

FIG. 2A shows the steps of multi-level circular simulation using scalar processing and the disclosed stream estimation steps of the disclosed method.

FIG. 2B shows the stream estimation and an example circuit (four-NANDs XOR) for reconvergence.

FIG. 2C provides truth tables that are used to analyze the outputs of the gates.

FIG. 3 provides a chart comparing the mean absolute error (MAE) performance between Sim2 and Sim3.

FIG. 4 provides an exemplar embodiment of a simulation of a four-NANDs XOR for actual bitstreams programmed in MATLAB®.

FIG. 5 provides an exemplar embodiment of a contingency table programmed in MATLAB®.

FIG. 6 provides an additional exemplar embodiment of a simulation of a four-NANDs XOR for scalar processing programmed in MATLAB®.

### BACKGROUND OF THE INVENTION

Stream processing is a form of programming paradigm that utilizes streams or sequences of events in time as the inputs and outputs of computation. In recent years, bit-stream processing systems have emerged as an attractive alternative paradigm for achieving efficient and robust outcomes in a variety of applications. Bit-stream processing involves the representation of data as a stream of bits, typically used in stochastic and unary computing systems. The primitive data representation is a bit-stream, which accumulates values of logic-1s across a bit-stream of size N. Bit-stream computing approach offers a new perspective on lightweight hardware design for machine learning but requires a testable environment for design space exploration. To this end, prior works offered little frameworks for hardware and software simulation of bit-stream processing systems.

Previous approaches have been proposed for stochastic computing (SC) circuit synthesis and simulation. Prior studies introduced tools like “scsynth” and “BitSAD” to facilitate the generation and analysis of SC circuits. scsynth, an open-source synthesis tool, focuses on generating Verilog designs based on architectures utilizing stochastic logic, with consideration for spectral transform techniques in stochastic circuit synthesis (STRAUSS). Similarly, BitSAD serves as a domain-specific language tailored for bit-stream processing systems, enabling the implementation of complex algorithms within resource-constrained environments. While these existing solutions provide valuable contributions to SC circuit simulation, they are based on actual bit-streams that may cause time-consuming processing.

Simulation of such circuits and systems is a valuable process for testing and improving computing systems. Simulations allow users to evaluate and understand how a system will behave under various conditions and test a plurality of inputs without needing to undergo the expense of building physical hardware or run real-time experiments. Specific to bitstreams, bitstream process simulations can test how a system will behave when fed continuous streams of binary data in the form of bitstreams. This work is especially relevant in digital signal processing, communication systems, and hardware implementations. The simulation can allow the user ability to assess optimization goals (e.g., compression, encryption, and transmission efficiency), timing (e.g., propagation delay, synchronization, and clock-domain interactions, and performance (e.g., throughput, latency, and real-time processing capabilities) before committing to the cost and expenditure of a hardware design.

Simulation is particularly vital in the stochastic computing context, which uses bitstreams to represent numbers, and the proportion of ones to zeros encodes the probability or value. Since stochastic computing inherently relies on randomness, simulations assist users in analyzing how errors and noise affect the computational accuracy. Simulations provide notable improvements in resource utilization analysis, where by simulating various logic functions and designs can assist the user in determining allowable trade-offs between precision, hardware complexity and energy efficiency.

### SUMMARY OF THE INVENTION

The method presented herein introduces a novel approach by utilizing scalar-only values, allowing the generation of stochastic logic results in software without the need for bitwise operations and importantly considering the reconvergent paths. It offers control over critical parameters such as correlation, random fluctuations, random sources, and reconvergence behavior, thereby effectively influencing signal correlations. In summary, this innovation sets itself apart by offering a unique methodology that enhances simulation accuracy and efficiency through the use of scalar-only values while addressing key challenges associated with SC circuit synthesis and simulation, including reconvergence behavior and signal correlations.

A new tool, CT, short for “Contingency Table,” imitates actual bit-streams but without generating long bit-level sequences. Instead, it works with scalar numbers. The method utilizes design principles of CT for runtime- and memory-efficient simulation of bit-stream processing systems. Proposed here is a method to efficiently and rapidly simulate multi-level circuits for bit-stream processing.

The invention presents a simulation method for bit-stream processing systems, specifically focusing on multi-level cascaded circuits with reconvergent paths, which may occur in the hardware of image processing and neural network systems. The simulation method addresses the challenge of efficiently simulating such complex circuits by introducing a scalar table-based reconvergent path-aware simulation. The functioning of this invention involves several key components and processes: (1) Stream Estimation: The method starts by estimating the expected values at mid-levels of cascaded logic circuits. This estimation is crucial for accurately predicting the behavior of the circuit without performing exhaustive bit-level simulations. (2) Reconvergence Awareness: Unlike traditional simulation methods, this invention considers reconvergent paths in the circuit. Reconvergence refers to the convergence of signal paths at different points within the circuit. By recognizing and accounting for reconvergence, the simulator better captures signal correlations and improves accuracy. (3) Scalar Processing: The simulation operates at a scalar level, avoiding the need to generate and process long bit-level sequences. Instead, it works with scalar numbers, which allows for faster and more memory-efficient simulation in capturing the reconvergences. (4) Correlation Manipulation: The simulator manipulates the correlation between input signals to optimize simulation accuracy. It considers maximum, minimum, and zero correlation scenarios to tailor the simulation process accordingly. The simulator is validated over some simulations, including a Four-NANDs XOR circuit and a 2-bit ripple carry adder. Performance metrics such as mean absolute error (MAE) and runtime are used to assess the effectiveness of the invention.

### DETAILED DESCRIPTION OF THE INVENTION

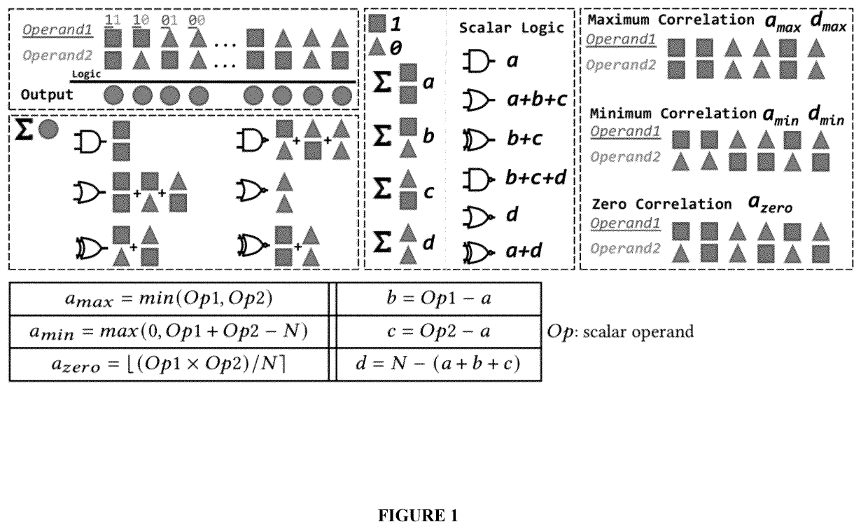

Given the randomized and iterative nature of bit-stream size, N, developing a fast and efficient method for bit-stream processing is challenging in terms of runtime and memory. FIG. 1 depicts the processing of two bit-stream operands, where each bit overlaps at every position.

Each bit undergoes a logic operation, and following N cycles, the output bit-stream is processed. Each bit in the output, represented by a circle [symbol] , can then be accumulated. The results derived from differing logic operations can be expressed via the cumulative counts of overlapping elements: [symbol] and [symbol] . The total number of symbol overlaps can be denotated as a, b, c, and d. Consider the output bit-stream of the AND operation, which is based on the total occurrence of [symbol] between operands. Hence, the total number of 1s at the output accumulation, denoted by [symbol] , is equal to a. By establishing relationship between symbols, input scalars and N, the bit-stream generation and logic processing can be eliminated, as scalar logic exists, as shown in FIG. 1.

This design process can be effectively initiated through: maximum, minimum, and zero correlation. FIG. 1 elucidates the cases with maximally, minimally correlated, or uncorrelated operands while taking into account the overlapping of identical symbols [symbol] and [symbol] . The implementation of maximum correlation guarantees that a reaches maximum value, whereas minimum correlation ensures its minimum. Therefore, a assumes critical significance. The a and the zero-correlation case are intrinsically linked through the utilization of cross-correlation optimization. The methodology is presented in FIG. 1.

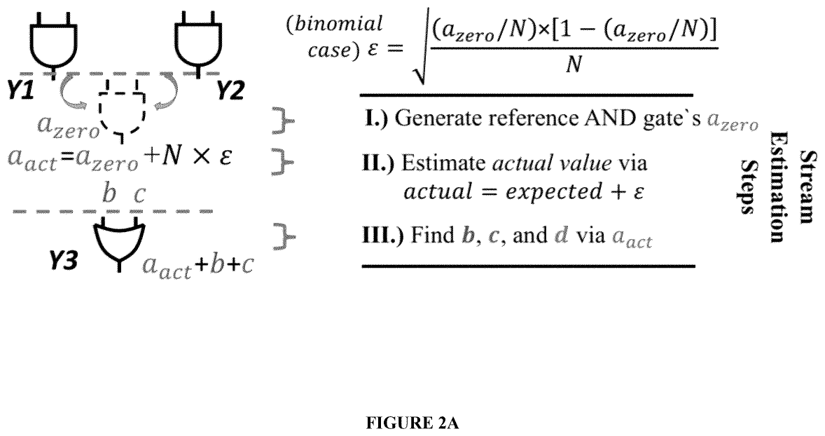

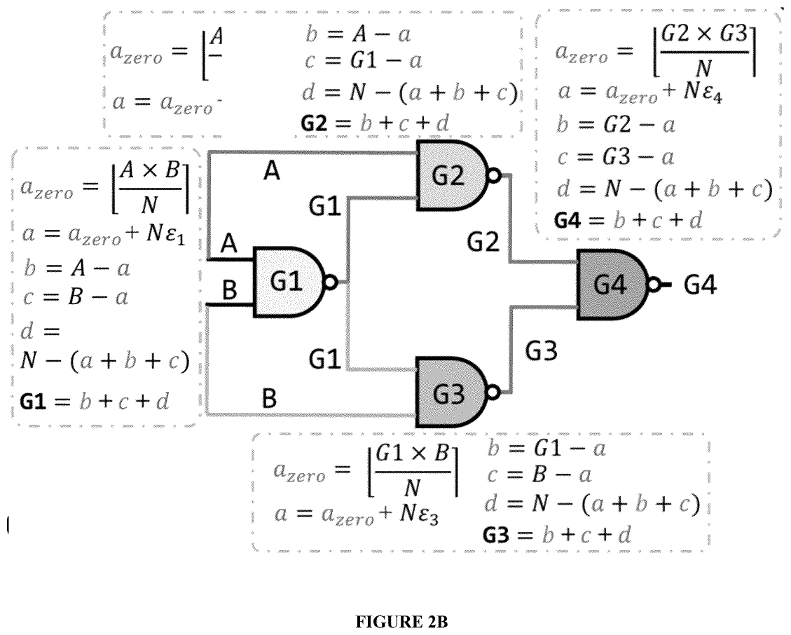

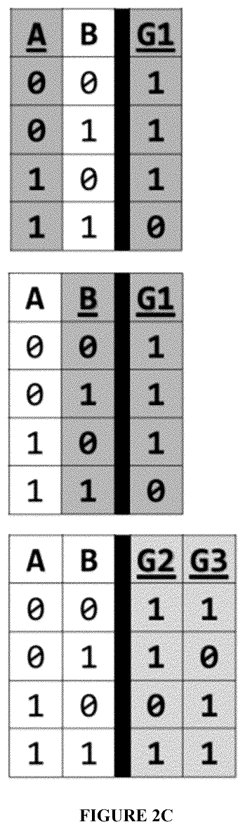

Stream estimation has the potential to adapt reconvergence concepts to digital bit-stream processing. For emulation of multi-level circuits, consider a 2-input (X1 and X2) AND gate. The expected value at the gate's output, denoted by P_{Y}, is calculated as [symbol] [X1×X2]= [symbol] [X1]× [symbol] [X2]=P_{X1}×P_{X2}=P_{Y}, where the inputs are independent random variables. The difference between the exact value (P_{Y}) and the obtained value reflects the random fluctuations error. The squared error provides a measure of the random fluctuation, which can be quantified by σ²=P_{Y}×(1−P_{Y}) for Bernoulli random values. As σ is a function of P_{Y} and N, the type of circuit is less significant, and the AND gate can serve as a reference gate due to its importance in scalar processing. FIG. 2A illustrates the steps of multi-level circuit simulation using scalar processing and the proposed stream estimation steps depicted in FIG. 1. Zero correlation is used to obtain an expected value for the AND gate. This is essential since e necessitates it for standard deviation calculation in the binomial case. That is, ε=σ=\sqrt{P_{Y}(1−P_{Y})/N}, where

$${P}_{Y} = {P}_{Y 1} \times {P}_{Y 2} = \frac{{a}_{zero}}{N} .$$

Nevertheless, the expected value deviates from the actual value. To tackle this, use the deviation calculation related to the random source through ε, and the expected value is estimated (via a_{zero}), giving rise to a_{act}. FIG. 2B illustrates the stream estimation and also an exemplar circuit (four-NANDs XOR) for reconvergence. The circuit paths that exhibit reconvergence are highlighted. Truth tables in FIG. 2C are used to analyze the outputs of gates. Observed in the yellow-colored loop, A and G1 never have a ‘00’ state, resulting in signal correlation for G2. This holds true for gates G3 and G4. The outputs of the gates do not possess a ‘00’ state in the colored loops, and there is a correlation—called reconvergence. The user must then sent the corresponding d symbol (00) to a minimum, thus setting a to a minimum as well: aₘᵢₙ=max(0, Op1+Op2−N). As a result, the formulas for G2, G3, and G4 in FIG. 2B are initialized using aₘᵢₙ instead of a_{zero}.

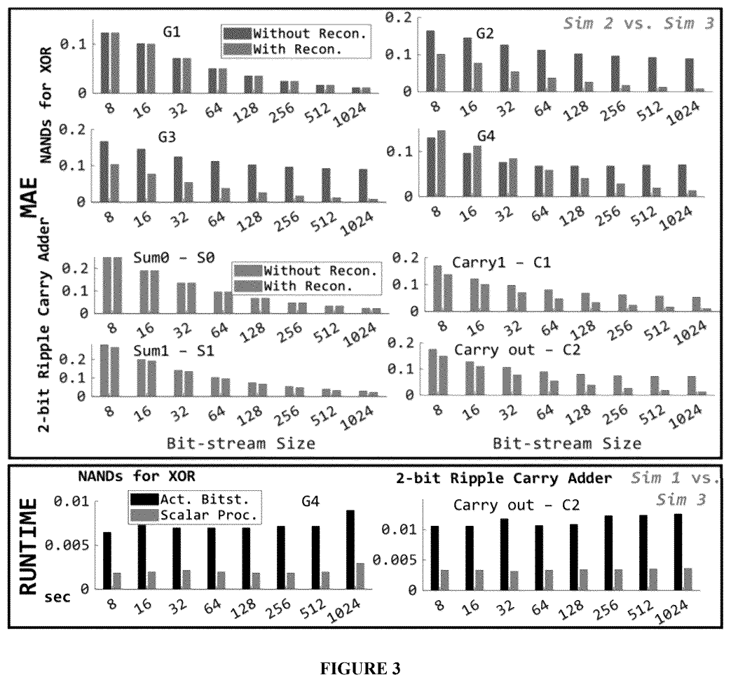

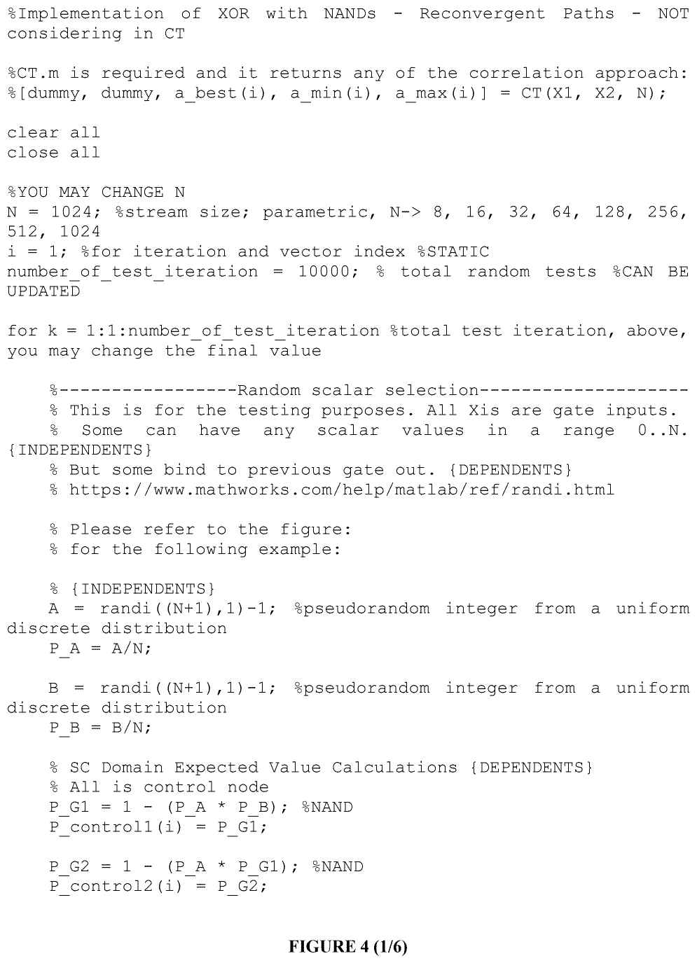

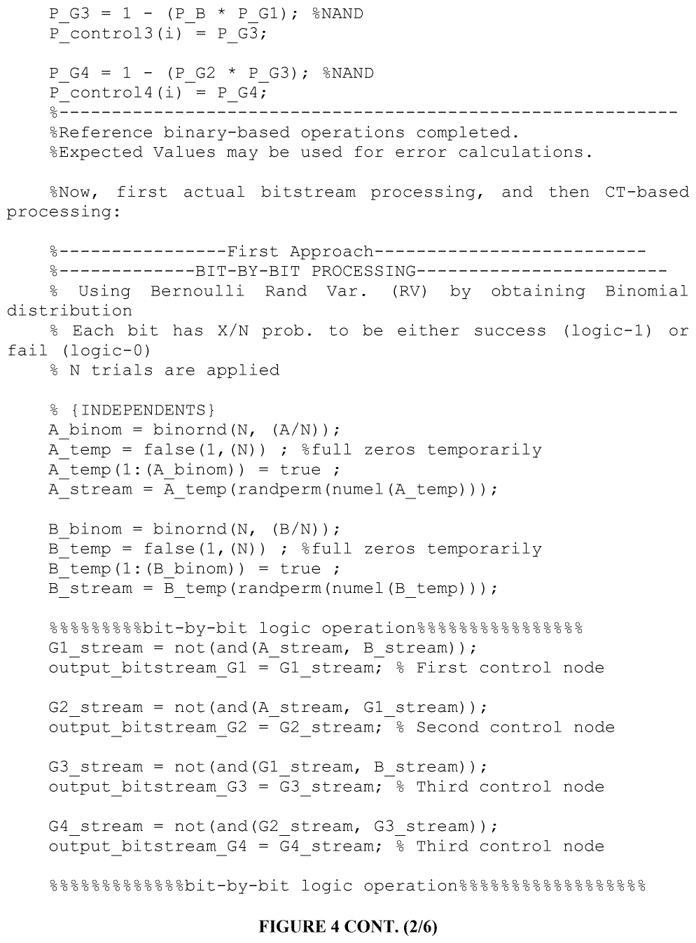

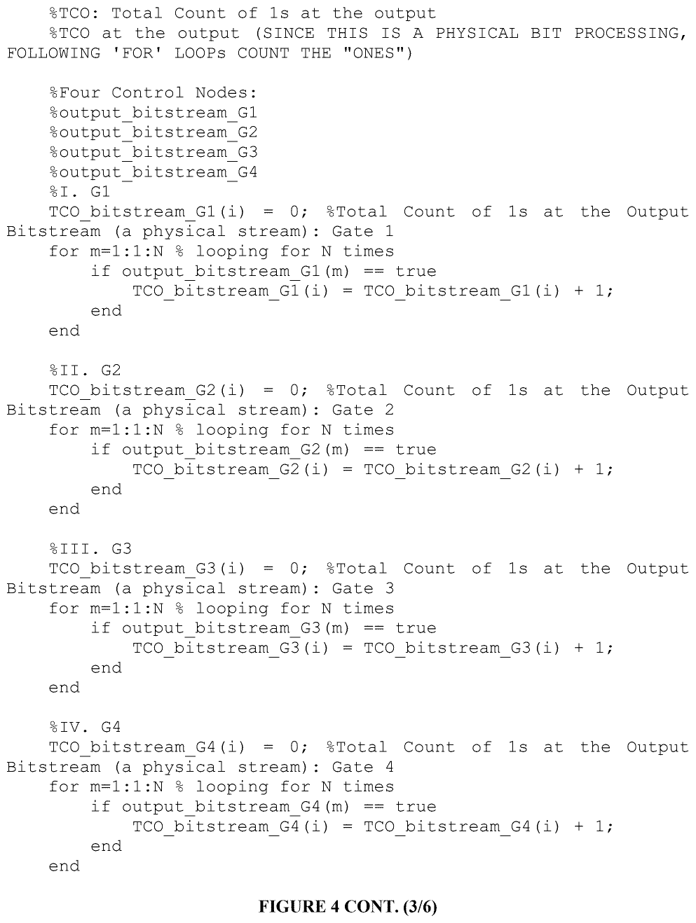

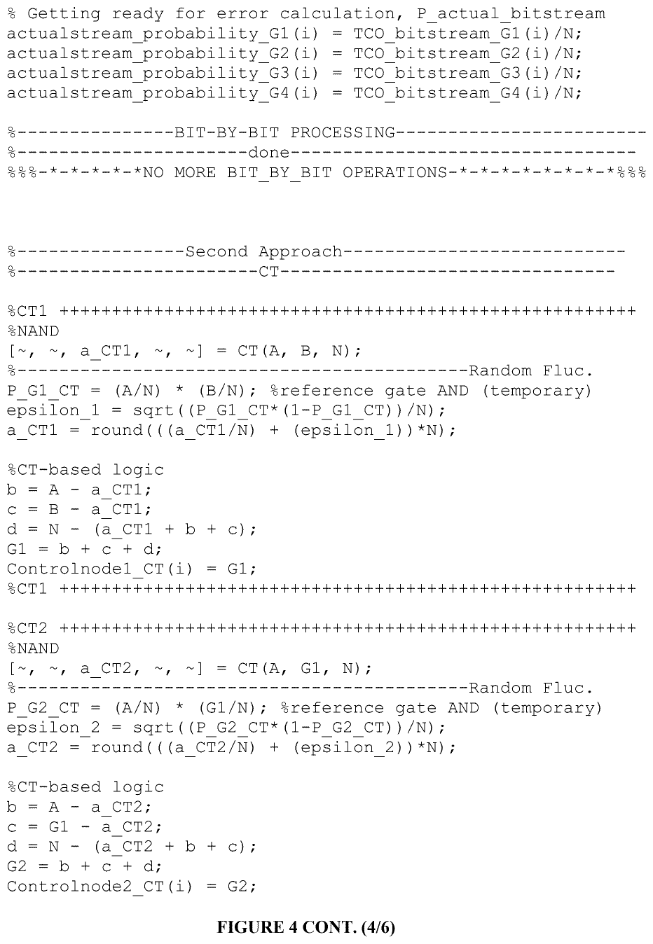

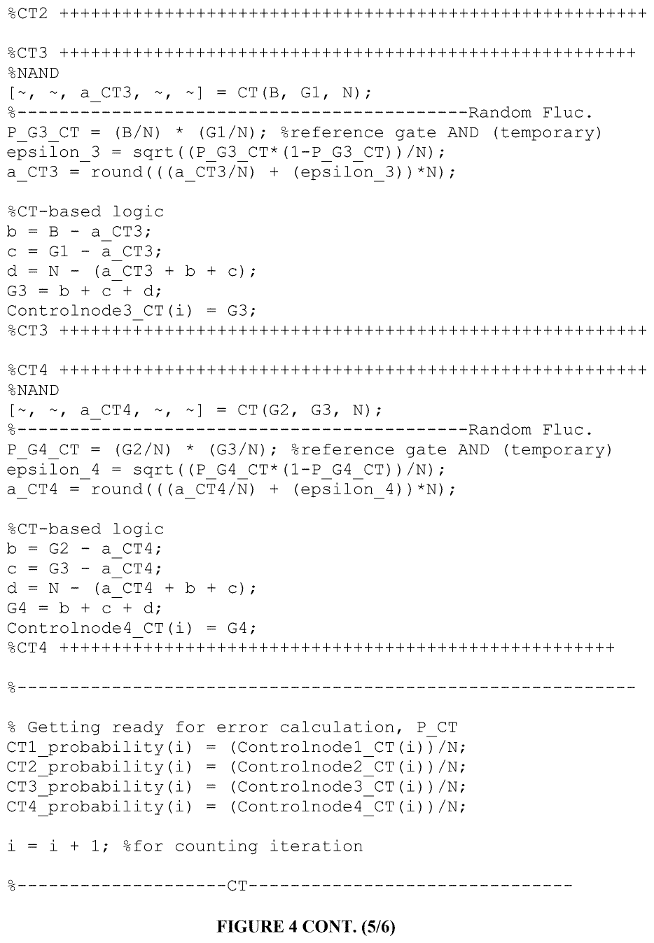

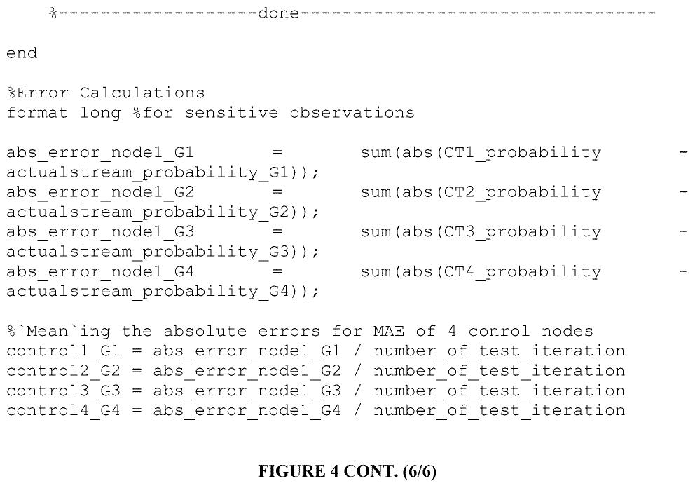

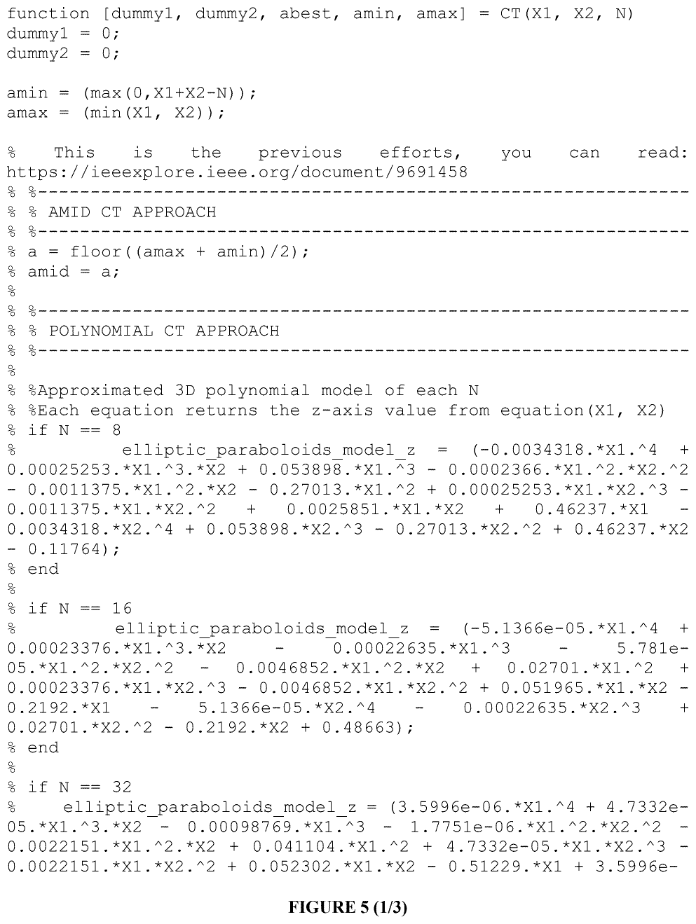

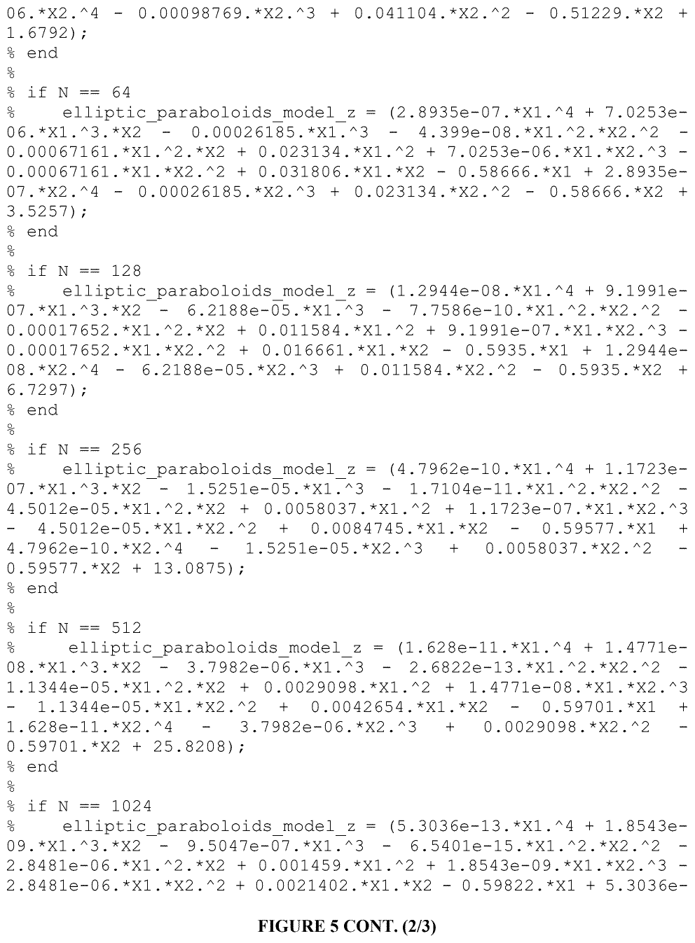

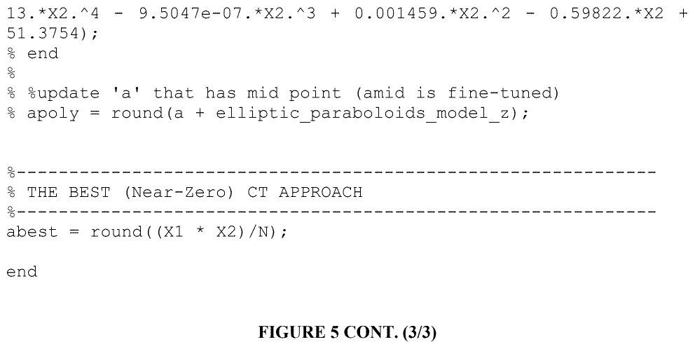

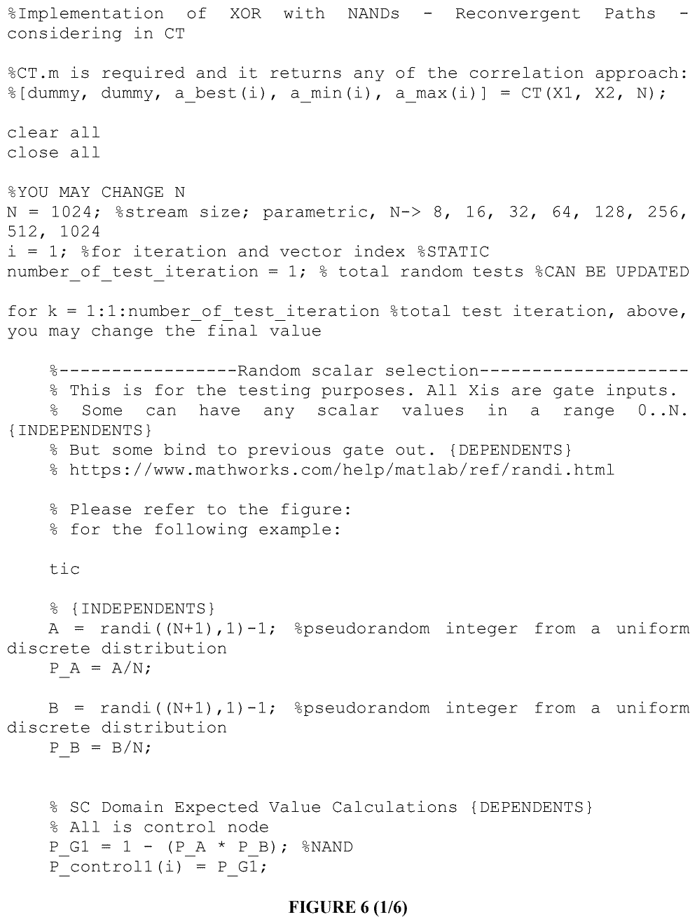

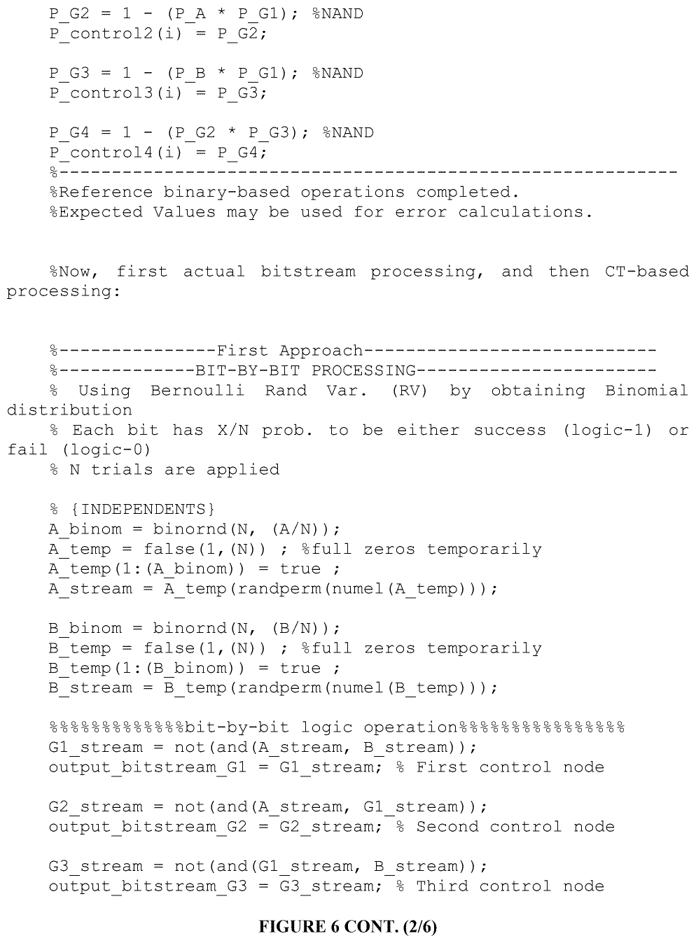

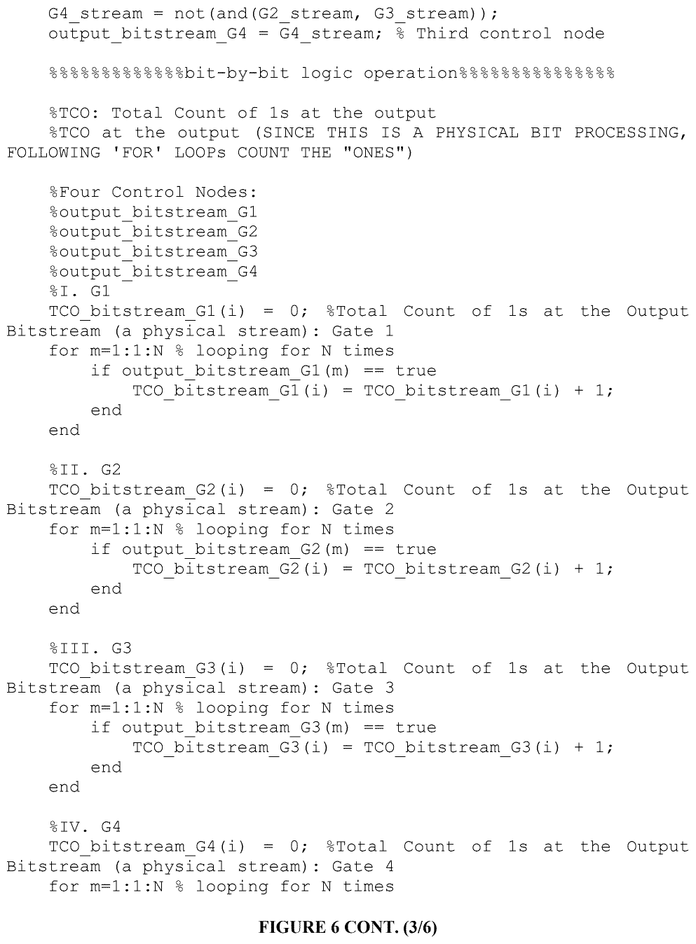

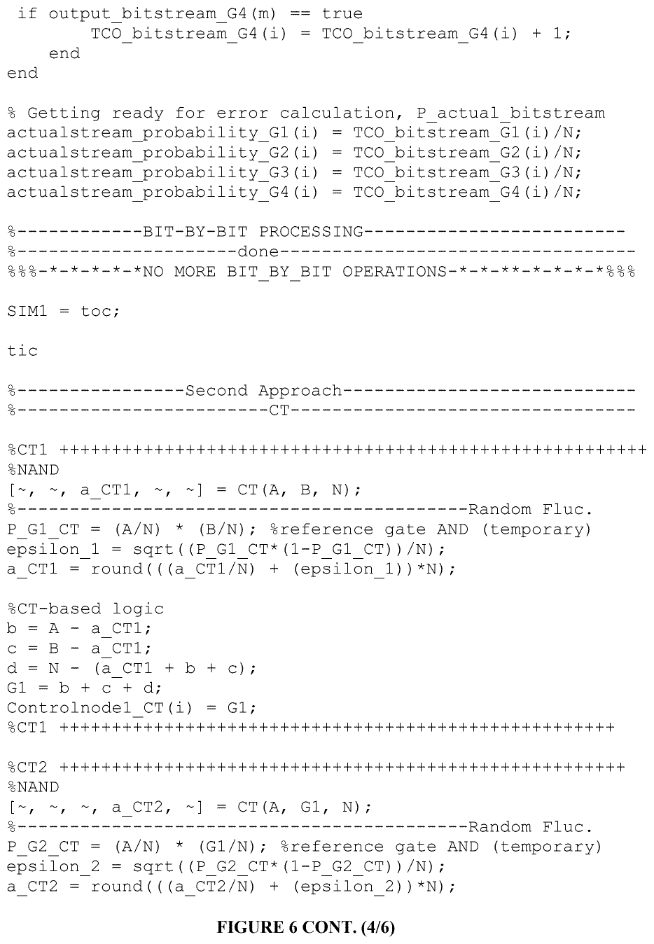

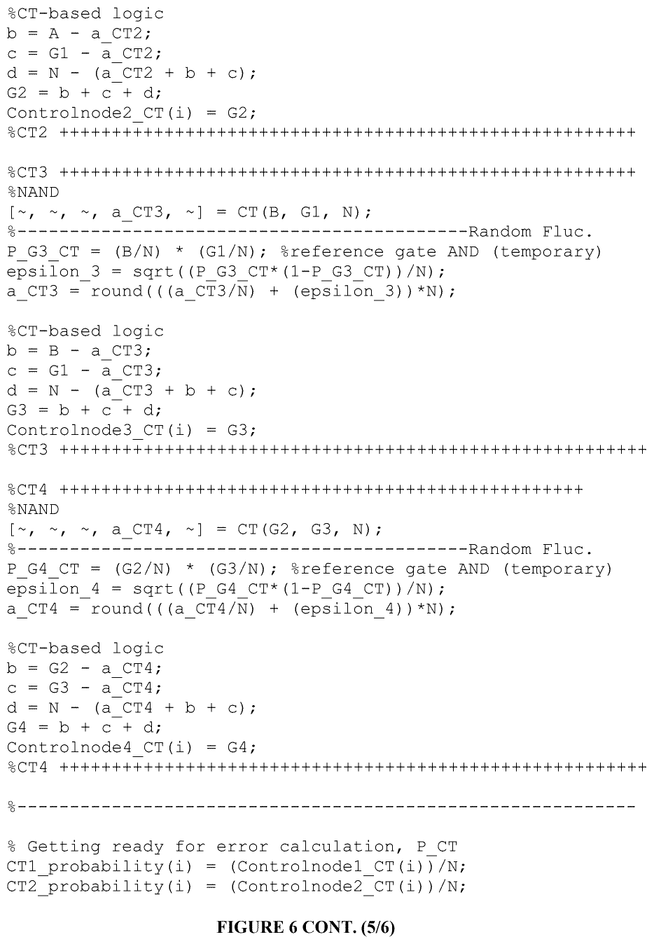

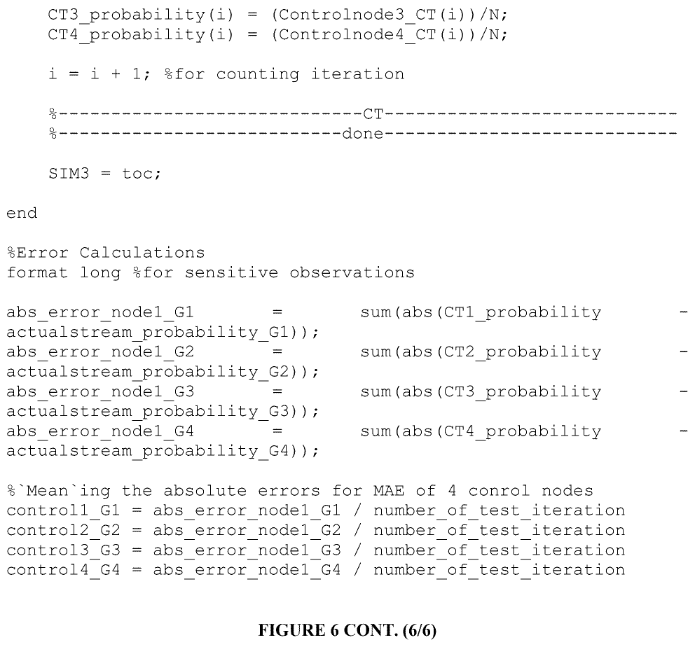

Next simulated are: (i) a four-NANDs XOR (which can be implemented using the coding in FIG. 4 and FIG. 6) and (ii) a 2-bit ripple carry adder (which can be implemented using the coding in Appendix 1 and Appendix 2). The latter topology is more complex with four cascading levels and ten gates to analyze; Sum and Carry outputs (S0, S1, C1, C2) are checked. Each topology is evaluated with two simulation approaches: Sim1 for actual bit-streams and Sim2 for scalar processing. We utilize binomial random sources. Over 10,000 random iterations, each Sim accepts random inputs either as bit-streams or directly as scalars. The checkpoints in each topology (G1, G2, G3, G4 in (i) and & S0, S1, C1, C2 in (ii)) are compared using mean absolute error (MAE) between Sim1 and Sim2; hence, the performance of simulator is measured with respect to real bit-streams. Sim2 does not use the reconvergence concept and follows the always-set-a_{zero} approach in FIG. 2B. Nevertheless, one more simulation, Sim3, considers the reconvergent paths and initiates scalar processing symbols considering signal correlations. FIG. 3 compares the MAE performance between Sim2 and Sim3. The reconvergence0aware simulation gives better results, especially for the longer bit-stream size. FIG. 3 also compares the run-time performance of Sim1 and Sim3.

The subject matter of the present invention is described with specificity herein to meet statutory requirements. However, the description itself is not intended to necessarily limit the scope of claims. Rather, the claimed subject matter might be embodied in other ways to include different steps or combinations of steps like the ones described in this document, in conjunction with other present or future technologies. Although the terms “step” and/or “block” or “module” etc. might be used herein to connote different components of methods or systems employed, the terms should not be interpreted as implying any specific order among or between various steps herein disclosed unless and except when the order of individual steps is explicitly described.

Furthermore, the described features, structures, or characteristics may be combined in any suitable manner in one or more embodiments. Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment.

Moreover, the terms “substantially” or “approximately” as used herein may be applied to modify any quantitative representation that could permissibly vary without resulting in a change to the basic function to which it is related.

We claim:

1. A method for improving simulation of a multi-level cascaded circuit in bit-stream processing systems comprising:
(a) Identifying the multi-level cascaded circuit to be simulated;
(b) Identifying at least two bit-streams, wherein:
each bit-stream comprising a plurality of bits, wherein each bit is in a position within the bit-stream; and each bit of a bit-stream overlaps with a bit of another bit-stream at every position;
(c) Identifying a plurality of bit-stream processing paths in the multi-level cascaded circuit;
(d) Construct a contingency table;
(e) Applying a logic operation to each bit in each bit-stream to generate an output bit-stream;
(f) Accumulating each bit in the output bit-stream;
(g) Calculating an expected value of the output bit-stream of the logic operation;
(h) Calculating an error measure of the expected value of the output bit-stream;
(i) Identifying one or more reconvergences in the multi-level cascaded circuit; and
(j) For each reconvergence, calculating an actual value of the output bit-stream by adding the expected value of the output bit-stream and the error measure.

2. The method of claim 1, wherein the one or more reconvergent paths comprise one or more points where two or more bit-stream processing paths merge, comprising areas of the multi-level cascaded circuit with possible correlation challenges.

3. The method of claim 1, wherein each result from each logic operation comprises a cumulative count of one or more overlapping elements in the at least two bit-streams.

4. The method of claim 1, wherein constructing the contingency table comprises:
(a) Categorizing each bit in each bit-stream into a distinct state; and
(b) Generating a table comprising how each state of a bit interacts with other states of a bit after passing through one or more logic operations.

5. The method of claim 1, further comprising calculating a measure of random fluctuation of the output bit-stream.
